(19) United States
(12) Patent Application Publication
(10) Pub. No.: US 2017/0335468 A1
(43) Pub. Date: Nov. 23, 2017

(54) FUEL PRODUCTION METHOD AND FUEL PRODUCTION APPARATUS

(71) Applicant: Panasonic Intellectual Property Management Co., Ltd., Osaka (JP)

(72) Inventors: SHINYA OKAMOTO, Kyoto (JP); TAKEYUKI SEKIMOTO, Osaka (JP); MASAHIRO DEGUCHI, (US); SATOSHI YOTSUHASHI, Osaka (JP)

(21) Appl. No.: 15/413,484

(22) Filed: Jan. 24, 2017

(30) Foreign Application Priority Data
May 18, 2016 (JP) 2016-099364

(51) Int. Cl. C25B 1/00; H01L 31/068; C25B 3/04; H01G 9/20; C25B 1/04; C25B 11/04; H01L 31/0693; H01L 31/0224

(52) U.S. Cl. CPC C25B 1/003; H01L 31/0693; H01L 31/068; H01L 31/022425; H01G 9/205; C25B 1/04; H01G 9/2004; C25B 11/04; C25B 3/04; H01G 9/2045

(57) ABSTRACT

The present disclosure provides a fuel production method and a fuel production apparatus which efficiently convert solar light energy into a fuel. The fuel production apparatus of the present disclosure includes a laminate, an electrolytic bath, and a support tool or a proton permeable membrane. The laminate includes a photoelectromotive layer having a p-n junction structure, a cathode electrode, an anode electrode and a side surface insulating layer, and the photoelectromotive layer includes a semiconductor layer that absorbs light in a near-infrared region with a wavelength of 900 nm or more. In the fuel production apparatus, an underwater optical path length is set to an optimum design value, so that even light in a near-infrared region with a wavelength of 900 nm or more is sufficiently utilized to efficiently convert light energy into at least one fuel selected from hydrogen, carbon monoxide, formic acid, methane, ethylene, methanol, ethanol, isopropanol, allyl alcohol, acetaldehyde and propionaldehyde through a reduction reaction on the cathode electrode.

### BACKGROUND

### 1. Technical Field

The present disclosure relates to a fuel production method and a fuel production apparatus in which a photoelectromotive layer capable of utilizing even light in a near-infrared region (wavelength: 900 nm or more) is used underwater.

### 2. Description of the Related Art

Recently, due to a concern about depletion of fossil fuels, renewable energy such as solar light has attracted attention, but solar power generation has such a problem that stable supply of energy is difficult. Meanwhile, artificial photosynthesis techniques in which light energy is converted into a fuel such as a gas are expected to contribute to solution of energy problems by making it possible to store energy efficiently for a long period of time.

Currently, development of fuel cells utilizing hydrogen as energy is advanced, and in addition to infrastructure development and hydrogen storage techniques, hydrogen production techniques utilizing solar light energy are extensively studied.

Further, an increase in concentration of carbon dioxide on the earth due to discharge of an enormous amount of carbon dioxide from plants is a cause of global warming. Thus, techniques attract attention in which solar light is utilized to convert carbon dioxide into an organic substance that serves as a fuel.

PTLS 1 and 2 disclose a method for producing hydrogen by an apparatus including a solar cell as an electromotive source and having an electrolytic bath, a cathode electrode and an anode electrode each disposed on a side opposite to a light-receiving surface of the solar cell.

PTL 3 discloses a method for producing hydrogen and reducing carbon dioxide by an apparatus having a cathode electrode and an anode electrode disposed on a light-receiving surface of a photoelectromotive layer and a back surface of the photoelectromotive layer, respectively.

### CITATION LIST

### Patent Literatures

PTL 1: Unexamined Japanese Patent Publication No. 2004-197167

PTL 2: Unexamined Japanese Patent Publication No. 2012-41623

PTL 3: Unexamined Japanese Patent Publication No. 2015-183218

### SUMMARY

In one general aspect, the techniques disclosed here feature a fuel production method including:

(a) providing a fuel production apparatus including an electrolytic bath, a laminate and a support tool, wherein

the electrolytic bath holds an electrolytic solution,

the laminate includes a cathode electrode containing a metal or a metal compound, a photoelectromotive layer having a p-n junction structure, and an anode electrode,

the cathode electrode and the anode electrode are in contact with the electrolytic solution,

the p-n junction structure includes a p-type layer and an n-type layer,

the photoelectromotive layer includes at least one semiconductor layer that absorbs light in a near-infrared region (wavelength: 900 nm or more),

the cathode electrode is formed on the photoelectromotive layer on an n-type layer side,

the anode electrode is formed on the photoelectromotive layer on a p-type layer side,

a side surface insulating layer is formed on a side surface of the laminate, and

the laminate is supported in the electrolytic solution with surfaces of the anode electrode and the cathode electrode which are in contact with the electrolytic solution being insulated from each other by the support tool; and

(b) irradiating the cathode electrode with light to produce a fuel in the cathode electrode,

wherein

an optical path length of the light to a surface of the photoelectromotive layer in the electrolytic solution is 7 mm or less.

According to the above-mentioned aspect in which an underwater optical path length according to the present disclosure is designed, fuel production efficiency can be dramatically improved.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

It should be noted that general or specific embodiments may be implemented as a system, a method, an integrated circuit, a computer program, a storage medium, or any selective combination thereof.

### BRIEF DESCRIPTION OF THE DRAWINGS

FIG. 1A is a sectional view schematically showing one example of an exemplary embodiment of a laminate according to the present disclosure;

FIG. 1B is a sectional view schematically showing another example of the exemplary embodiment of the laminate according to the present disclosure;

FIG. 2A is a sectional view schematically showing one example of an exemplary embodiment of a fuel production apparatus according to the present disclosure;

FIG. 2B is a sectional view schematically showing another example of the exemplary embodiment of the fuel production apparatus according to the present disclosure;

FIG. 3 is a graph showing dependency of an absorption spectrum of water on an underwater optical path length in Example 1; and

FIG. 4 is a graph showing dependency on an underwater optical path length of I-V characteristics of a solar cell irradiated with simulated solar light transmitted through water in Example 1.

### DETAILED DESCRIPTION

Hereinafter, the present disclosure will be described with regard to exemplary embodiments thereof.

For improving energy conversion efficiency, studies on a photoelectromotive layer having high photoelectric conversion efficiency are extensively conducted. However, a system including a solar cell etc. as an external power source and having two electrodes electrically connected through a conducting wire has such a problem that an apparatus is complicated with an increase in scale, or resistance of the conducting wire causes a power loss. Therefore, development of a wireless integrated photoelectrochemical device attracts attention.

Apparatuses with such an integrated device wholly disposed in an electrolytic solution have been reported, but with consideration given to influences of absorption of light in a near-infrared region by water, a photoelectromotive layer that absorbs light in a near-infrared region is not used in many of these apparatuses. A configuration for reducing influences of absorption of light by water in the case of using a photoelectromotive layer that absorbs light in a near-infrared region has not been shown. In any case, it has been impossible to efficiently utilize light in a near-infrared region and improve energy conversion efficiency.

On the other hand, there have been reported integrated devices in which a photoelectromotive layer does not contact an electrolytic solution, but no fundamental solution has been attained because these devices have a very complicated configuration.

One non-limiting and exemplary embodiment provides a fuel production apparatus in which, by optimally setting an underwater optical path length to 7 mm or less, even light in a near-infrared region is sufficiently utilized to dramatically improve fuel production efficiency with a simple configuration.

A fuel production method according to one aspect of the present disclosure includes: (a) providing a fuel production apparatus including an electrolytic bath, a laminate and a support tool, wherein the electrolytic bath holds an electrolytic solution, the laminate includes a cathode electrode containing a metal or a metal compound, a photoelectromotive layer having a p-n junction structure, and an anode electrode, the cathode electrode and the anode electrode are in contact with the electrolytic solution, the p-n junction structure includes a p-type layer and an n-type layer, the photoelectromotive layer includes at least one semiconductor layer that absorbs light in a near-infrared region (wavelength: 900 nm or more), the cathode electrode is formed on the photoelectromotive layer on an n-type layer side, the anode electrode is formed on the photoelectromotive layer on a p-type layer side, a side surface insulating layer is formed on a side surface of the laminate, and the laminate is supported in the electrolytic solution with surfaces of the anode electrode and the cathode electrode which are in contact with the electrolytic solution being insulated from each other by the support tool; and (b) irradiating the cathode electrode with light to produce a fuel in the cathode electrode, wherein an optical path length of the light to a surface of the cathode electrode in the electrolytic solution is 7 mm or less.

According to the above-mentioned aspect, there can be provided a method capable of efficiently producing a fuel in a cathode electrode only by irradiating a photoelectromotive layer with light.

### Exemplary Embodiment

Hereinafter, a fuel production method and a fuel production apparatus according to an exemplary embodiment of the present disclosure will be described with reference to the drawings. The present disclosure is not limited to the exemplary embodiment shown below.

### (Laminate)

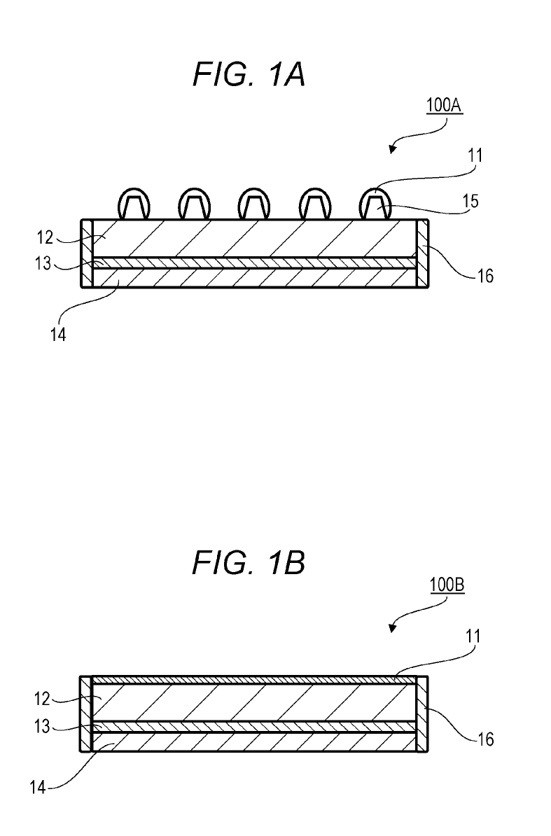

FIGS. 1A and 1B are schematic views showing one example of laminate 100A according to the present disclosure. Laminate 100A shown in FIG. 1A includes cathode electrode 11, photoelectromotive layer 12 having a p-n junction structure, electrically conductive base material 13, and anode electrode 14 from a light-irradiated surface side. Cathode electrode 11 is a reducing catalyst carried on surface electrode 15, and anode electrode 14 is an oxidizing catalyst that oxidizes water. Photoelectromotive layer 12 is a semiconductor layer having a p-n junction structure. Surface electrode 15 and an n-type layer of photoelectromotive layer 12 are electrically connected to each other. A p-type layer of photoelectromotive layer 12 is electrically connected to anode electrode 14 through electrically conductive base material 13. A side surface of laminate 100A is electrically insulated by side surface insulating layer 16.

Electrons produced by photo-excitation in photoelectromotive layer 12 move to a surface of cathode electrode 11, and react with protons or carbon dioxide to produce a fuel. Holes produced by photo-excitation move to a surface of anode electrode 14, and oxidize water to produce oxygen.

Preferably, anode electrode 14 is made from a material having a low oxygen generation overvoltage, such as iridium oxide (IrO₂), ruthenium oxide (RuO₂), iron (Fe) or nickel (Ni).

Cathode electrode 11 is a catalyst made from a metal (including a metal alloy) or a metal compound. Preferably, the metal (metal alloy) or metal compound contains at least one selected from platinum (Pt), gold (Au), indium (In), copper (Cu) and silver (Ag).

Side surface insulating layer 16 is made from a synthetic resin having high water resistance and chemical resistance, specifically, epoxy resin, acrylic resin, silicone resin, phenol resin or the like.

Photoelectromotive layer 12 has a junction structure of a p-type layer made from a material (semiconductor material) showing p-type characteristics and an n-type layer made from a material (semiconductor material) showing n-type characteristics. A material showing i-type characteristics may exist between the p-type layer and the n-type layer. Thus, the p-n junction structure of photoelectromotive layer 12 also includes a p-i-n junction structure. Similarly, the p-n junction structure of photoelectromotive layer 12 also includes a structure including a buffer layer introduced into a junction interface such as an interface between p-type and i-type layers or between i-type and n-type layers.

Generally, a material showing p-type characteristics and a material showing n-type characteristics are made from the same material, but different materials may form a p-n junction structure. Thus, the p-type layer and the n-type layer of photoelectromotive layer 12 may be made from mutually different semiconductors.

Photoelectromotive layer 12 may include a plurality of semiconductor layers. Here, it is preferable that photoelectromotive layer 12 has a pair of adjacent semiconductor layers in which the n-type layer of one semiconductor layer is electrically connected to the p-type layer of the other semiconductor layer. It is more preferable that in all semiconductor layers of photoelectromotive layer 12, the n-type layer (or p-type layer) of a semiconductor layer is electrically connected to the p-type layer (or n-type layer) of the adjacent semiconductor layer. The n-type layer of one semiconductor layer and the p-type layer of the other semiconductor layer are not necessarily required to be in direct contact with each other for establishing electrical connection. For example, the n-type layer of one semiconductor layer and the p-type layer of the other semiconductor layer may be electrically connected to each other with an electrically conductive layer interposed (held) therebetween. The electrically conductive layer is, for example, a transparent electrically conductive layer or an intermediate reflection layer.

Specific examples of materials of photoelectromotive layer 12 having a p-n junction structure include gallium arsenide (GaAs), indium gallium arsenide (InGaAs), silicon (Si) and germanium (Ge), and photoelectromotive layer 12 may also be a multi-junction semiconductor layer obtained by combining any of these materials with other materials. The p-n junction of photoelectromotive layer 12 is not particularly limited as long as photoelectromotive layer 12 contains at least one material that absorbs light in a near-infrared region (wavelength: 900 nm or more). In an example of the present disclosure, a tri-junction InGaP/GaAs/Ge structure having a p-n junction was used as photoelectromotive layer 12.

Laminate 100B shown in FIG. 1B includes cathode electrode 11, photoelectromotive layer 12 having a p-n junction structure, electrically conductive base material 13, and anode electrode 14 from a light-irradiated surface side. Cathode electrode 11 is a reducing catalyst formed in a film shape, and is electrically connected to the n-type layer of photoelectromotive layer 12. Laminate 100B otherwise has the same configuration as that of laminate 100A shown in FIG. 1A.

### (Fuel Production Apparatus)

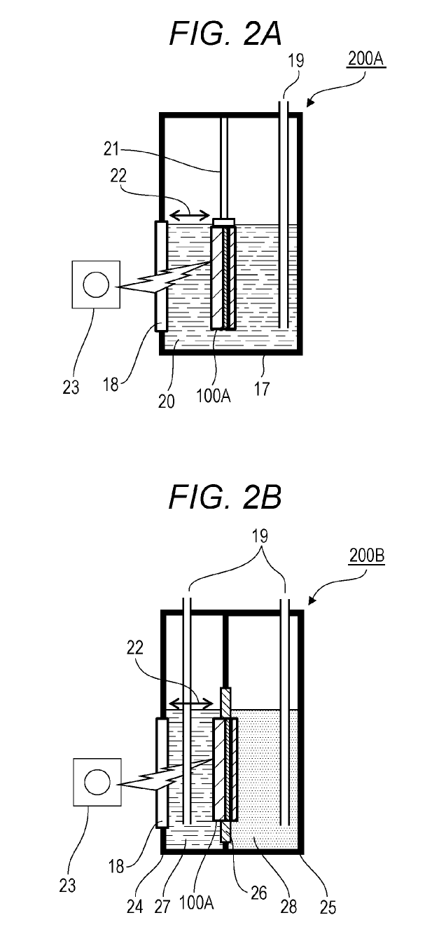

FIG. 2A is a schematic view showing one example of a fuel production apparatus for producing a fuel by photoirradiation using a laminate. Fuel production apparatus 200A includes electrolytic bath 17, quartz glass window 18 and gas introduction pipe 19, electrolytic solution 20 is held in electrolytic bath 17, and laminate 100A is supported by support tool 21. Laminate 100A is in contact with electrolytic solution 20. Specifically, laminate 100A is immersed in electrolytic solution 20. Support tool 21 is not required to be in contact with electrolytic solution 20. Underwater optical path length 22 can be set by, for example, design of support tool 21. Here, underwater optical path length 22 is an optical path length of light to a surface of photoelectromotive layer 12 in electrolytic solution 20 as shown in FIG. 2A. As electrolytic solution 20 held in electrolytic bath 17, a general electrolytic solution can be used, and particularly, an aqueous solution containing at least one of potassium hydrogen carbonate (KHCO₃) and sodium hydrogen carbonate (NaHCO₃) is preferable. A concentration of electrolytic solution 20 is preferably 0.5 mol/L or more irrespective of which electrolyte is contained. In the case of fuel production through a carbon dioxide reduction reaction, carbon dioxide is contained (dissolved) in electrolytic solution 20. A concentration of carbon dioxide contained in electrolytic solution 20 is not particularly limited. In place of laminate 100A, laminate 100B having a similar structure may be used. A configuration of the laminate is not limited as long as the laminate has a capability of producing a fuel such as hydrogen or carbon dioxide. Laminate 100A is supported in the electrolytic solution with surfaces of anode electrode 14 and cathode electrode 11 which are in contact with electrolytic solution 20 being insulated from each other by support tool 21. Owing to this support method, a short-circuit does not occur between the surfaces of anode electrode 14 and cathode electrode 11 which are in contact with electrolytic solution 20, and thus the device normally operates. A material of support tool 21 is preferably one having excellent water resistance, chemical resistance and insulation quality, specifically, Teflon (registered trademark), acrylic resin, phenol resin, glass or the like. When a metal material having high mechanical strength is used as a material of support tool 21, it is necessary that a material having water resistance, chemical resistance and insulation quality be interposed between a surface of the laminate and a surface of the metal material.

A region of laminate 100A which is immersed in electrolytic solution 20 is irradiated with light from light source 23 as described later. Specific examples of light source 23 include a xenon lamp, a mercury lamp and a halogen lamp, and these lamps can be used singly or in combination. Solar light can also be used as light source 23.

FIG. 2B is a schematic view showing another example of a fuel production apparatus for producing a fuel by photoirradiation using laminate 100A. Fuel production apparatus 200B includes cathode bath 24, anode bath 25 and proton permeable membrane 26. First electrolytic solution 27 is held in cathode bath 24, second electrolytic solution 28 is held in anode bath 25, and proton permeable membrane 26 and laminate 100A are sandwiched between both the baths. The light-irradiated surface side of laminate 100A is in contact with first electrolytic solution 27, and an anode electrode 14 side of laminate 100A is in contact with second electrolytic solution 28. Specifically, laminate 100A is immersed in first electrolytic solution 27 and second electrolytic solution 28 so as to be in contact with both first electrolytic solution 27 and second electrolytic solution 28. Underwater optical path length 22 can be set by apparatus design. As first electrolytic solution 27 held in cathode bath 24, a general electrolytic solution can be used, and particularly, an aqueous solution containing at least one of potassium hydrogen carbonate (KHCO₃), sodium hydrogen carbonate (NaHCO₃), potassium chloride (KCl) and sodium chloride (NaCl) is preferable. A concentration of the first electrolytic solution is preferably 0.5 mol/L or more irrespective of which electrolyte is contained. In the case of fuel production through a carbon dioxide reduction reaction, carbon dioxide is contained (dissolved) in first electrolytic solution 27. A concentration of carbon dioxide contained in first electrolytic solution 27 is not particularly limited. First electrolytic solution 27 is preferably acidic in a state in which carbon dioxide is dissolved in the electrolytic solution. Second electrolytic solution 28 held in anode bath 25 is, for example, an aqueous solution containing at least one of potassium hydrogen carbonate (KHCO₃), sodium hydrogen carbonate (NaHCO₃) and sodium hydroxide (NaOH). A concentration of an electrolyte in the second electrolytic solution is preferably 0.5 mol/L or more. Second electrolytic solution 28 is preferably basic. A region of laminate 100A on the light-irradiated surface side, which is immersed in first electrolytic solution 27, is irradiated with light from light source 23. Since laminate 100A and proton permeable membrane 26 are sandwiched between cathode bath 24 and anode bath 25, first electrolytic solution 27 and second electrolytic solution 28 are not mixed with each other in this apparatus. Proton permeable membrane 26 is not particularly limited as long as it is permeable to protons (H+) and impermeable to other substances. Specific examples of proton permeable membrane 26 include a Nafion (registered trademark) membrane.

### (Method for Producing Fuel by Photoirradiation)

A method for producing a fuel using the above-mentioned apparatus will now be described.

Fuel production apparatuses 200A and 200B can be placed at room temperature under atmospheric pressure. As shown in FIGS. 2A and 2B, a light-receiving surface of laminate 100A is irradiated with light from light source 23. Examples of light source 23 include a simulated solar light source and solar light. Light applied from such a light source includes light in a near-infrared region (wavelength: 900 nm or more).

Preferably, each of fuel production apparatuses 200A and 200B includes gas introduction pipe 19 as shown in FIGS. 2A and 2B. In a reduction treatment of carbon dioxide, it is preferable that carbon dioxide contained in electrolytic solution 20 or first electrolytic solution 27 is reduced while carbon dioxide is supplied to electrolytic solution 20 or first electrolytic solution 27 through gas introduction pipe 19. One end of gas introduction pipe 19 is immersed in electrolytic solution 20 or first electrolytic solution 27. Preferably, a sufficient amount of carbon dioxide is dissolved in electrolytic solution 20 or first electrolytic solution 27 by supply of carbon dioxide through gas introduction pipe 19 before reduction of carbon dioxide is started. Cathode electrode 11 having an appropriate catalyst layer is disposed in electrolytic bath 17 or cathode bath 24, and laminate 100A or 100B is irradiated with light to produce a fuel. As a result, hydrogen (H₂), carbon monoxide (CO), hydrocarbons such as formic acid (HCOOH), methane (CH₄) and ethylene (C₂H₄), alcohols such as ethanol (C₂H₅OH), aldehydes and so on can be produced as reduction products. A main catalyst layer material to be used in the apparatus and method according to the present disclosure is a material including gold, indium, copper, silver, platinum or the like, and it is also possible to change a kind of the product by selecting a kind of the material. For example, the metal or metal compound of cathode electrode 11 may be gold, a gold alloy or a gold compound, and carbon monoxide may be obtained by reduction of carbon dioxide. The metal or metal compound of cathode electrode 11 may be indium, an indium alloy or an indium compound, and formic acid may be obtained by reduction of carbon dioxide. The metal or metal compound of cathode electrode 11 may be copper, a copper alloy or a copper compound, and at least one of methane, ethylene, ethanol and acetaldehyde may be obtained by reduction of carbon dioxide. The metal or metal compound of cathode electrode 11 may be silver, a silver alloy or a silver compound, and carbon monoxide may be obtained by reduction of carbon dioxide. The metal or metal compound of cathode electrode 11 may be platinum, a platinum alloy or a platinum compound, and hydrogen may be obtained by water decomposition.

### EXAMPLES

The present disclosure will be described more in detail with reference to examples below. The present disclosure is not limited to examples below.

### Example 1

(Design of Underwater Optical Path Length 22)

Underwater optical path length 22 according to the present disclosure, with consideration given to absorption of light in a near-infrared region by water, was designed.

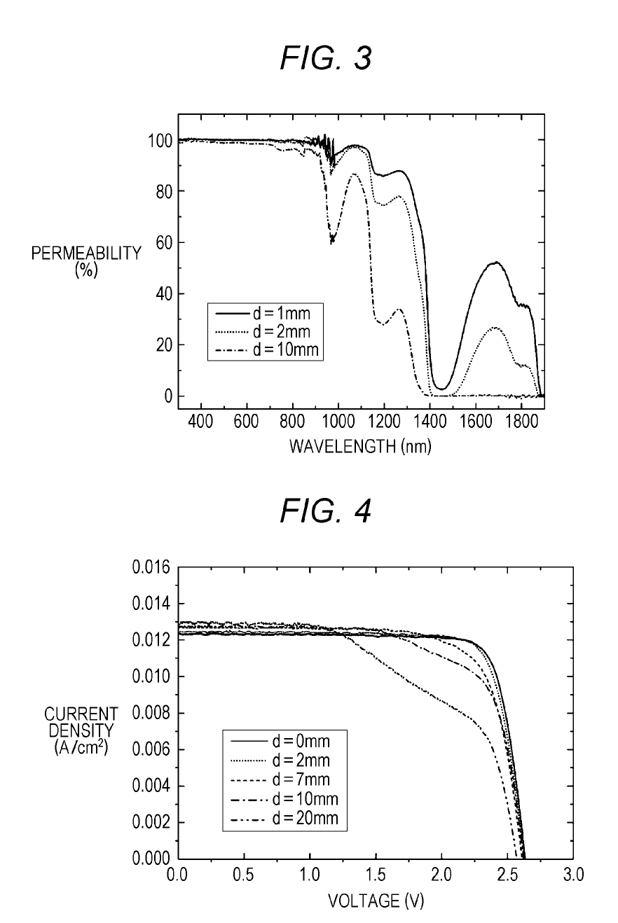

First, a rectangular quartz container was filled with water, and set on a stage of a spectrophotometer in such a manner that reference light was vertically incident on two opposite flat surfaces of the container. A permeability of water to light in a wavelength region of 300 nm to 1800 nm was measured. Results of the measurement showed that the permeability decreased due to underwater optical path length-dependent absorption of light in a near-infrared region (FIG. 3).

Next, the container was disposed between a solar cell and a simulated solar light source each disposed in air, and I-V characteristics of the solar cell (tri-junction compound semiconductor solar cell; InGaP/GaAs/Ge) were examined. As a result, it was shown that when the underwater optical path length was 7 mm or more, solar cell performance was deteriorated (FIG. 4). This is caused by absorption of light in a near-infrared region by water as shown by results in FIG. 3. It has been shown that in the solar cell used, a bottom cell (Ge) as a layer which absorbs light in a near-infrared region is more abundant in generated current in comparison with a top cell and a middle cell, and therefore when the underwater optical path length is set to 7 mm or less, it is possible to make the best use of solar cell performance.

### Example 2

In Example 2, laminate 100A shown in FIG. 1A was used. Photoelectromotive layer 12 included the solar cell used in Example 1. Cathode electrode 11 contained platinum (Pt) as a catalyst for generating hydrogen from water, and anode electrode 14 on a back surface contained iridium oxide (IrO₂) as a catalyst for generating oxygen from water. For electrically conductive base material 13, stainless steel was used, and electrically conductive base material 13 was fixed to anode electrode 14 using an electrically conductive copper double-sided tape. For side surface insulating layer 16, epoxy resin was used.

Laminate 100A was supported by support tool 21, and fuel production apparatus 200A with underwater optical path length 22 set to 7 mm was prepared. For electrolytic solution 20, a 3.0 mol/L potassium hydrogen carbonate aqueous solution was used. For support tool 21, acrylic resin was used. For light source 23, a simulated solar light source (irradiation light amount: 100 mW/cm²) was used.

Dissolved gases were removed from electrolytic solution 20 by subjecting electrolytic solution 20 to an Ar gas bubbling treatment (flow rate: 200 mL/min) through gas introduction pipe 19 for 60 minutes. Thereafter, a light-receiving surface of laminate 100A was irradiated with simulated solar light for 10 minutes to advance a photoelectrochemical reaction.

By performing gas chromatography to analyze gas phase components, it was confirmed that 177.1 μmol of hydrogen was produced as a result of this example.

### Comparative Example 1

In Comparative Example 1, fuel production apparatus 200A was prepared under the same conditions as in Example 2 except that underwater optical path length 22 was set to 50 mm, and a light-receiving surface of laminate 100A was irradiated with simulated solar light for 10 minutes to advance a photoelectrochemical reaction.

By analyzing components in the same manner as in Example 2, it was confirmed that 19.3 μmol of hydrogen was produced as a result of this comparative example. Thus, hydrogen production efficiency was lower in comparison with Example 2. This means that in Comparative Example 1, underwater optical path length 22 was not set in an optimum range designed in Example 1, and therefore influences of absorption of light in a near-infrared region by water caused deterioration of performance of photoelectromotive layer 12 and laminate 100A, resulting in reduction of hydrogen production efficiency. Thus, it has been shown that the exemplary embodiment shown in Example 2 of the present disclosure is superior in production of hydrogen to Comparative Example 1 which employs a conventional structure.

### Example 3

In Example 3, laminate 100A shown in FIG. 1A was used. Photoelectromotive layer 12 included the solar cell used in Example 1. Cathode electrode 11 contained gold (Au) as a catalyst for reducing carbon dioxide in water, and anode electrode 14 on a back surface contained iridium oxide (IrO₂) as a catalyst for generating oxygen from water. For electrically conductive base material 13, stainless steel was used, and electrically conductive base material 13 was fixed to anode electrode 14 using an electrically conductive copper double-sided tape. For side surface insulating layer 16, epoxy resin was used.

Laminate 100A was supported by support tool 21, and fuel production apparatus 200A with underwater optical path length 22 set to 7 mm was prepared. For electrolytic solution 20, a 0.5 mol/L potassium hydrogen carbonate aqueous solution was used. For support tool 21, acrylic resin was used. For light source 23, a simulated solar light source (irradiation light amount: 100 mW/cm²) was used.

Dissolved gases were removed from electrolytic solution 20 by subjecting electrolytic solution 20 to an Ar gas bubbling treatment (flow rate: 200 mL/min) through gas introduction pipe 19 for 60 minutes. Further, a carbon dioxide gas was supplied to electrolytic solution 20 through gas introduction pipe 19 for 90 minutes by a bubbling treatment. Thereafter, a light-receiving surface of laminate 100A was irradiated with simulated solar light for 20 minutes to advance a photoelectrochemical reaction.

By analyzing components in the same manner as in Example 2, it was confirmed that a synthetic gas including 28.0 μmol of carbon monoxide and 104.0 μmol of hydrogen was produced as a result of this example.

### Comparative Example 2

In Comparative Example 2, fuel production apparatus 200A was prepared under the same conditions as in Example 3 except that underwater optical path length 22 was set to 50 mm, and a light-receiving surface of laminate 100A was irradiated with simulated solar light for 20 minutes to advance a photoelectrochemical reaction.

By analyzing components in the same manner as in Example 2, it was confirmed that a synthetic gas including 8.0 μmol of carbon monoxide and 56.4 μmol of hydrogen was produced as a result of this comparative example. Thus, production efficiency of carbon monoxide and hydrogen was lower in comparison with Example 3. This means that in Comparative Example 2, underwater optical path length 22 was not set in an optimum range designed in Example 1, and therefore influences of absorption of light in a near-infrared region by water caused deterioration of performance of photoelectromotive layer 12 and laminate 100A, resulting in reduction of hydrogen production efficiency. Thus, it has been shown that the exemplary embodiment shown in Example 3 of the present disclosure is superior in reduction of carbon dioxide to Comparative Example 2 which employs a conventional structure.

### Example 4

In Example 4, laminate 100A shown in FIG. 1A was used. Photoelectromotive layer 12 included the solar cell used in Example 1. Cathode electrode 11 contained copper (Cu) as a catalyst for reducing carbon dioxide in water, and anode electrode 14 on a back surface contained iridium oxide (IrO₂) as a catalyst for generating oxygen from water. For electrically conductive base material 13, stainless steel was used, and electrically conductive base material 13 was fixed to anode electrode 14 using an electrically conductive copper double-sided tape. For side surface insulating layer 16, epoxy resin was used.

Laminate 100A was supported by support tool 21, and fuel production apparatus 200A with underwater optical path length 22 set to 7 mm was prepared. For electrolytic solution 20, a 0.5 mol/L potassium hydrogen carbonate aqueous solution was used. For support tool 21, acrylic resin was used. For light source 23, a simulated solar light source (irradiation light amount: 100 mW/cm²) was used.

Dissolved gases were removed from electrolytic solution 20 by subjecting electrolytic solution 20 to an Ar gas bubbling treatment (flow rate: 200 mL/min) through gas introduction pipe 19 for 60 minutes. Further, a carbon dioxide gas was supplied to electrolytic solution 20 through gas introduction pipe 19 for 90 minutes by a bubbling treatment. Thereafter, a light-receiving surface of laminate 100A was irradiated with simulated solar light for 20 minutes to advance a photoelectrochemical reaction.

By analyzing components in the same manner as in Examples 2 and 3, it was confirmed that hydrocarbon components such as methane and ethylene, alcohol components such as ethanol, and aldehyde components such as acetaldehyde which were not produced in Examples 2 and 3 were produced as a result of this example. It was confirmed that hydrogen, carbon monoxide and formic acid were produced as other components.

### Summary of Exemplary Embodiment of the Present Disclosure

A fuel production method according to one aspect of the present disclosure includes: (a) providing a fuel production apparatus including an electrolytic bath, a laminate and a support tool, wherein the electrolytic bath holds an electrolytic solution, the laminate includes a cathode electrode containing a metal or a metal compound, a photoelectromotive layer having a p-n junction structure, and an anode electrode, the cathode electrode and the anode electrode are in contact with the electrolytic solution, the p-n junction structure includes a p-type layer and an n-type layer, the photoelectromotive layer includes at least one semiconductor layer that absorbs light in a near-infrared region (wavelength: 900 nm or more), the cathode electrode is formed on the photoelectromotive layer on an n-type layer side, the anode electrode is formed on the photoelectromotive layer on a p-type layer side, a side surface insulating layer is formed on a side surface of the laminate, and the laminate is supported in the electrolytic solution with surfaces of the anode electrode and the cathode electrode which are in contact with the electrolytic solution being insulated from each other by the support tool; and (b) irradiating the cathode electrode with light to produce a fuel in the cathode electrode, wherein an optical path length of the light to a surface of the cathode electrode in the electrolytic solution is 7 mm or less.

According to one aspect of the present disclosure, fuel production efficiency can be dramatically improved by setting the underwater optical path length to 7 mm or less.

In the above-mentioned aspect, for example, light to be applied to the photoelectromotive layer may include light having a wavelength of 900 nm or more.

In the above-mentioned aspect, for example, the metal may be platinum, and in the step (b), hydrogen may be obtained as a fuel by water decomposition.

According to the above-mentioned aspect, hydrogen (H₂) can be efficiently produced as a water decomposition reaction product.

In the above-mentioned aspect, for example, the metal compound may be at least one selected from the group consisting of a platinum alloy and a platinum compound, and in the step (b), hydrogen may be obtained as a fuel by water decomposition.

According to the above-mentioned aspect, hydrogen (H₂) can be efficiently produced as a water decomposition reaction product.

In the above-mentioned aspect, for example, carbon dioxide may be dissolved in the electrolytic solution, the metal may be gold, and in the step (b), carbon monoxide may be obtained as a fuel by reduction of the carbon dioxide.

According to the above-mentioned aspect, a synthetic gas containing a hydrogen (H₂) component can be efficiently produced with a carbon monoxide (CO) component formed as a reaction product as a result of subjecting carbon dioxide to a reduction treatment.

In the above-mentioned aspect, for example, carbon dioxide may be dissolved in the electrolytic solution, the metal compound may be at least one selected from the group consisting of a gold alloy and a gold compound, and in the step (b), carbon monoxide may be obtained as a fuel by reduction of the carbon dioxide.

According to the above-mentioned aspect, a synthetic gas containing a hydrogen (H₂) component can be efficiently produced with a carbon monoxide (CO) component formed as a reaction product as a result of subjecting carbon dioxide to a reduction treatment.

In the above-mentioned aspect, for example, carbon dioxide may be dissolved in the electrolytic solution, the metal may be indium, and in the step (b), formic acid may be obtained as a fuel by reduction of the carbon dioxide.

According to the above-mentioned aspect, a formic acid (HCOOH) component can be efficiently produced as a reaction product as a result of subjecting carbon dioxide to a reduction treatment.

In the above-mentioned aspect, for example, carbon dioxide may be dissolved in the electrolytic solution, the metal compound may be at least one selected from the group consisting of an indium alloy and an indium compound, and in the step (b), formic acid may be obtained as a fuel by reduction of the carbon dioxide.

According to the above-mentioned aspect, a formic acid (HCOOH) component can be efficiently produced as a reaction product as a result of subjecting carbon dioxide to a reduction treatment.

In the above-mentioned aspect, for example, carbon dioxide may be dissolved in the electrolytic solution, the metal may be copper, and in the step (b), at least one of methane, ethylene, ethanol and acetaldehyde may be obtained as a fuel by reduction of the carbon dioxide.

According to the above-mentioned aspect, hydrocarbon components such as methane (CH₄) and ethylene (C₂H₄) and alcohol components such as ethanol (C₂H₅OH) can be obtained as reaction products as a result of subjecting carbon dioxide to a reduction treatment.

In the above-mentioned aspect, for example, carbon dioxide may be dissolved in the electrolytic solution, the metal compound may be at least one selected from the group consisting of a copper alloy and a copper compound, and in the step (b), at least one of methane, ethylene, ethanol and acetaldehyde may be obtained as a fuel by reduction of the carbon dioxide.

According to the above-mentioned aspect, hydrocarbon components such as methane (CH₄) and ethylene (C₂H₄) and alcohol components such as ethanol (C₂H₅OH) can be obtained as reaction products as a result of subjecting carbon dioxide to a reduction treatment.

In the above-mentioned aspect, for example, carbon dioxide may be dissolved in the electrolytic solution, the metal may be silver, and in the step (b), carbon monoxide may be obtained as a fuel by reduction of the carbon dioxide.

According to the above-mentioned aspect, a synthetic gas containing a hydrogen (H₂) component can be efficiently produced with a carbon monoxide (CO) component formed as a reaction product as a result of subjecting carbon dioxide to a reduction treatment.

In the above-mentioned aspect, for example, carbon dioxide may be dissolved in the electrolytic solution, the metal compound may be at least one selected from the group consisting of a silver alloy and a silver compound, and in the step (b), carbon monoxide may be obtained as a fuel by reduction of the carbon dioxide.

According to the above-mentioned aspect, a synthetic gas containing a hydrogen (H₂) component can be efficiently produced with a carbon monoxide (CO) component formed as a reaction product as a result of subjecting carbon dioxide to a reduction treatment.

In the above-mentioned aspect, the photoelectromotive layer may be made from at least one selected from the group consisting of gallium arsenide (GaAs), indium gallium arsenide (InGaAs), silicon (Si) and germanium (Ge).

In the above-mentioned aspect, for example, the electrolytic solution may be an aqueous solution containing at least one of potassium hydrogen carbonate and sodium hydrogen carbonate.

According to the above-mentioned aspect, such an electrolytic solution is suitable as an electrolytic solution that is stored in an electrolytic bath.

In the above-mentioned aspect, for example, a photoelectrochemical apparatus may be installed at room temperature under atmospheric pressure in the step (b).

According to the above-mentioned aspect, a fuel is produced by light energy without installing the photoelectrochemical apparatus in a special environment.

A fuel production method according to another aspect of the present disclosure includes: (a) providing a fuel production apparatus including a cathode bath, an anode bath, a proton permeable membrane and a laminate, wherein the cathode bath holds a first electrolytic solution, the anode bath holds a second electrolytic solution, the cathode bath and the anode bath are separated by the proton permeable membrane and the laminate, the laminate includes a cathode electrode containing a metal or a metal compound, a photoelectromotive layer having a p-n junction structure, and an anode electrode, the cathode electrode is in contact with the first electrolytic solution, the anode electrode is in contact with the second electrolytic solution, the p-n junction structure includes a p-type layer and an n-type layer, the photoelectromotive layer includes at least one semiconductor layer that absorbs light in a near-infrared region (wavelength: 900 nm or more), the cathode electrode is formed on the photoelectromotive layer on an n-type layer side, and the anode electrode is formed on the photoelectromotive layer on a p-type layer side; and (b) irradiating the cathode electrode with light to produce a fuel in the cathode electrode, wherein an optical path length of the light to a surface of the cathode electrode in the electrolytic solution is 7 mm or less.

According to one aspect of the present disclosure, fuel production efficiency can be dramatically improved by setting the underwater optical path length to 7 mm or less.

In the above-mentioned aspect, for example, light to be applied to the photoelectromotive layer may include light having a wavelength of 900 nm or more.

In the above-mentioned aspect, for example, the metal may be platinum, and in the step (b), hydrogen may be obtained as a fuel by water decomposition.

According to the above-mentioned aspect, hydrogen (H₂) can be efficiently produced as a water decomposition reaction product.

In the above-mentioned aspect, for example, the metal compound may be at least one selected from the group consisting of a platinum alloy and a platinum compound, and in the step (b), hydrogen may be obtained as a fuel by water decomposition.

According to the above-mentioned aspect, hydrogen (H₂) can be efficiently produced as a water decomposition reaction product.

In the above-mentioned aspect, for example, carbon dioxide may be dissolved in the electrolytic solution, the metal may be gold, and in the step (b), carbon monoxide may be obtained as a fuel by reduction of the carbon dioxide.

According to the above-mentioned aspect, a synthetic gas containing a hydrogen (H₂) component can be efficiently produced with a carbon monoxide (CO) component formed as a reaction product as a result of subjecting carbon dioxide to a reduction treatment.

In the above-mentioned aspect, for example, carbon dioxide may be dissolved in the electrolytic solution, the metal compound may be at least one selected from the group consisting of a gold alloy and a gold compound, and in the step (b), carbon monoxide may be obtained as a fuel by reduction of the carbon dioxide.

According to the above-mentioned aspect, a synthetic gas containing a hydrogen (H₂) component can be efficiently produced with a carbon monoxide (CO) component formed as a reaction product as a result of subjecting carbon dioxide to a reduction treatment.

In the above-mentioned aspect, for example, carbon dioxide may be dissolved in the electrolytic solution, the metal may be indium, and in the step (b), formic acid may be obtained as a fuel by reduction of the carbon dioxide.

According to the above-mentioned aspect, a formic acid (HCOOH) component can be efficiently produced as a reaction product as a result of subjecting carbon dioxide to a reduction treatment.

In the above-mentioned aspect, for example, carbon dioxide may be dissolved in the electrolytic solution, the metal compound may be at least one selected from the group consisting of an indium alloy and an indium compound, and in the step (b), formic acid may be obtained as a fuel by reduction of the carbon dioxide.

According to the above-mentioned aspect, a formic acid (HCOOH) component can be efficiently produced as a reaction product as a result of subjecting carbon dioxide to a reduction treatment.

In the above-mentioned aspect, for example, carbon dioxide may be dissolved in the electrolytic solution, the metal may be copper, and in the step (b), at least one of methane, ethylene, ethanol and acetaldehyde may be obtained as a fuel by reduction of the carbon dioxide.

According to the above-mentioned aspect, hydrocarbon components such as methane (CH₄) and ethylene (C₂H₄) and alcohol components such as ethanol (C₂H₅OH) can be obtained as reaction products as a result of subjecting carbon dioxide to a reduction treatment.

In the above-mentioned aspect, for example, carbon dioxide may be dissolved in the electrolytic solution, the metal compound may be at least one selected from the group consisting of a copper alloy and a copper compound, and in the step (b), at least one of methane, ethylene, ethanol and acetaldehyde may be obtained as a fuel by reduction of the carbon dioxide. In the above-mentioned aspect, for example, carbon dioxide may be dissolved in the electrolytic solution, the metal may be silver, and in the step (b), carbon monoxide may be obtained as a fuel by reduction of the carbon dioxide. According to the above-mentioned aspect, a synthetic gas containing a hydrogen (H₂) component can be efficiently produced with a carbon monoxide (CO) component formed as a reaction product as a result of subjecting carbon dioxide to a reduction treatment.

In the above-mentioned aspect, for example, carbon dioxide may be dissolved in the electrolytic solution, the metal compound may be at least one selected from the group consisting of a silver alloy and a silver compound, and in the step (b), carbon monoxide may be obtained as a fuel by reduction of the carbon dioxide.

According to the above-mentioned aspect, a synthetic gas containing a hydrogen (H₂) component can be efficiently produced with a carbon monoxide (CO) component formed as a reaction product as a result of subjecting carbon dioxide to a reduction treatment.

In the above-mentioned aspect, the photoelectromotive layer may be made from at least one selected from the group consisting of gallium arsenide (GaAs), indium gallium arsenide (InGaAs), silicon (Si) and germanium (Ge).

In the above-mentioned aspect, for example, the first electrolytic solution may be an aqueous solution containing at least one of potassium hydrogen carbonate, sodium hydrogen carbonate, potassium chloride and sodium chloride.

According to the above-mentioned aspect, such an electrolytic solution is suitable as an electrolytic solution that is stored in a cathode bath.

In the above-mentioned aspect, for example, the second electrolytic solution may be an aqueous solution containing at least one of potassium hydrogen carbonate, sodium hydrogen carbonate and sodium hydroxide.

According to the above-mentioned aspect, such an electrolytic solution is suitable as an electrolytic solution that is stored in an anode bath.

In the above-mentioned aspect, for example, a photoelectrochemical apparatus may be installed at room temperature under atmospheric pressure in the step (b).

According to the above-mentioned aspect, a fuel is produced by light energy without installing the photoelectrochemical apparatus in a special environment.

A fuel production apparatus according to another aspect of the present disclosure includes: an electrolytic bath; a laminate; and a support tool, wherein the electrolytic bath holds an electrolytic solution, the laminate includes a cathode electrode containing a metal or a metal compound, a photoelectromotive layer having a p-n junction structure, and an anode electrode, the cathode electrode and the anode electrode are in contact with the electrolytic solution, the p-n junction structure includes a p-type layer and an n-type layer, the photoelectromotive layer has a p-n junction structure, and includes at least one semiconductor layer that absorbs light in a near-infrared region (wavelength: 900 nm or more), the cathode electrode is formed on the photoelectromotive layer on an n-type layer side, the anode electrode is formed on the photoelectromotive layer on a p-type layer side, a side surface insulating layer is formed on a side surface of the laminate, the laminate is supported in the electrolytic solution with surfaces of the anode electrode and the cathode electrode which are in contact with the electrolytic solution being insulated from each other by the support tool, and an optical path length of the light to a surface of the cathode electrode in the electrolytic solution is 7 mm or less.

A fuel production apparatus according to still another aspect of the present disclosure includes: a cathode bath, an anode bath, a proton permeable membrane and a laminate, wherein the cathode bath holds a first electrolytic solution, the anode bath holds a second electrolytic solution, the cathode bath and the anode bath are separated by the proton permeable membrane and the laminate, the laminate includes a cathode electrode containing a metal or a metal compound, a photoelectromotive layer having a p-n junction structure, and an anode electrode, the cathode electrode is in contact with the first electrolytic solution, the anode electrode is in contact with the second electrolytic solution, the p-n junction structure includes a p-type layer and an n-type layer, the photoelectromotive layer includes at least one semiconductor layer that absorbs light in a near-infrared region (wavelength: 900 nm or more), the cathode electrode is formed on the photoelectromotive layer on an n-type layer side, the anode electrode is formed on the photoelectromotive layer on a p-type layer side, and an optical path length of the light to a surface of the cathode electrode in the electrolytic solution is 7 mm or less.

The present disclosure provides a novel fuel production apparatus and a novel fuel production method in which even light in a near-infrared region (wavelength: 900 nm or more) is utilized to dramatically improve fuel production efficiency.

### REFERENCE SIGNS LIST

100A, 100B laminate

11 cathode electrode

12 photoelectromotive layer

13 electrically conductive base material

14 anode electrode

15 surface electrode

16 side surface insulating layer

200A, 200B fuel production apparatus

17 electrolytic bath

18 quartz glass window

19 gas introduction pipe

20 electrolytic solution

21 support tool

22 underwater optical path length

23 light source

24 cathode bath

25 anode bath

26 proton permeable membrane

27 first electrolytic solution

28 second electrolytic solution

What is claimed is:

1. A fuel production method comprising:
(a) providing a fuel production apparatus comprising an electrolytic bath, a laminate and a support tool, wherein
the electrolytic bath holds an electrolytic solution,
the laminate includes a cathode electrode containing a metal or a metal compound, a photoelectromotive layer having a p-n junction structure, and an anode electrode,
the cathode electrode and the anode electrode are in contact with the electrolytic solution,
the p-n junction structure includes a p-type layer and an n-type layer,
the photoelectromotive layer includes at least one semiconductor layer capable of absorbing light in a near-infrared region having a wavelength of not less than 900 nm,
the cathode electrode is formed on the photoelectromotive layer on an n-type layer side,
the anode electrode is formed on the photoelectromotive layer on a p-type layer side,
a side surface insulating layer is formed on a side surface of the laminate, and
the laminate is supported in the electrolytic solution with surfaces of the anode electrode and the cathode electrode which are in contact with the electrolytic solution being insulated from each other by the support tool; and
(b) irradiating the cathode electrode with light to produce a fuel in the cathode electrode,
wherein
an optical path length of the light to a surface of the photoelectromotive layer in the electrolytic solution is not more than 7 mm.

2. The fuel production method according to claim 1, wherein
the light in the step (b) includes light having a wavelength of not less than 900 nm.

3. The fuel production method according to claim 1, wherein
the metal is platinum, and
in the step (b), hydrogen is obtained as a fuel.

4. The fuel production method according to claim 1, wherein
the metal compound is at least one selected from the group consisting of a platinum alloy and a platinum compound, and
in the step (b), hydrogen is obtained as a fuel.

5. The fuel production method according to claim 1, wherein
carbon dioxide is dissolved in the electrolytic solution,
the metal is gold, and
in the step (b), carbon monoxide is obtained as a fuel by reduction of the carbon dioxide.

6. The fuel production method according to claim 1, wherein
carbon dioxide is dissolved in the electrolytic solution,
the metal compound is at least one selected from the group consisting of a gold alloy and a gold compound, and
in the step (b), carbon monoxide is obtained as a fuel by reduction of the carbon dioxide.

7. The fuel production method according to claim 1, wherein
carbon dioxide is dissolved in the electrolytic solution,
the metal is indium, and
in the step (b), formic acid is obtained as a fuel by reduction of the carbon dioxide.

8. The fuel production method according to claim 1, wherein
carbon dioxide is dissolved in the electrolytic solution,
the metal compound is at least one selected from the group consisting of an indium alloy and an indium compound, and
in the step (b), formic acid is obtained as a fuel by reduction of the carbon dioxide.

9. The fuel production method according to claim 1, wherein
carbon dioxide is dissolved in the electrolytic solution,
the metal is copper, and
in the step (b), at least one selected from the group consisting of methane, ethylene, ethanol and acetaldehyde is obtained as a fuel by reduction of the carbon dioxide.

10. The fuel production method according to claim 1, wherein
carbon dioxide is dissolved in the electrolytic solution,
the metal compound is at least one selected from the group consisting of a copper alloy and a copper compound, and
in the step (b), at least one selected from the group consisting of methane, ethylene, ethanol and acetaldehyde is obtained as a fuel by reduction of the carbon dioxide.

11. The fuel production method according to claim 1, wherein
carbon dioxide is dissolved in the electrolytic solution,
the metal is silver, and
in the step (b), carbon monoxide is obtained as a fuel by reduction of the carbon dioxide.

12. The fuel production method according to claim 1, wherein
carbon dioxide is dissolved in the electrolytic solution,
the metal compound is at least one selected from the group consisting of a silver alloy and a silver compound, and
in the step (b), carbon monoxide is obtained as a fuel by reduction of the carbon dioxide.

13. The fuel production method according to claim 1, wherein
the photoelectromotive layer is formed of at least one selected from the group consisting of gallium arsenide, indium gallium arsenide, silicon and germanium.

14. The fuel production method according to claim 1, wherein
the electrolytic solution is an aqueous solution containing at least one selected from the group consisting of potassium hydrogen carbonate and sodium hydrogen carbonate.

15. The fuel production method according to claim 1, wherein
a photoelectrochemical apparatus is left at rest at room temperature under atmospheric pressure in the step (b).

16. A fuel production apparatus comprising:
an electrolytic bath;
a laminate; and
a support tool,
wherein
the electrolytic bath holds an electrolytic solution,
the laminate includes a cathode electrode containing a metal or a metal compound, a photoelectromotive layer having a p-n junction structure, and an anode electrode,
the cathode electrode and the anode electrode are in contact with the electrolytic solution,
the p-n junction structure includes a p-type layer and an n-type layer,
the photoelectromotive layer includes at least one semiconductor layer that absorbs light in a near-infrared region having a wavelength of not less than 900 nm,
the cathode electrode is formed on the photoelectromotive layer on an n-type layer side,
the anode electrode is formed on the photoelectromotive layer on a p-type layer side,
a side surface insulating layer is formed on a side surface of the laminate,
the laminate is supported in the electrolytic solution with surfaces of the anode electrode and the cathode electrode which are in contact with the electrolytic solution being insulated from each other by the support tool, and
an optical path length of the light to a surface of the photoelectromotive layer in the electrolytic solution is not more than 7 mm.

17. A fuel production apparatus comprising:
a cathode bath;
an anode bath;
a proton permeable membrane; and
a laminate,
wherein
the cathode bath holds a first electrolytic solution,
the anode bath holds a second electrolytic solution,
the cathode bath and the anode bath are separated by the proton permeable membrane and the laminate,
the laminate includes a cathode electrode containing a metal or a metal compound, a photoelectromotive layer having a p-n junction structure, and an anode electrode,
the cathode electrode is in contact with the first electrolytic solution,
the anode electrode is in contact with the second electrolytic solution,
the p-n junction structure includes a p-type layer and an n-type layer,
the photoelectromotive layer includes at least one semiconductor layer that absorbs light in a near-infrared region having a wavelength of not less than 900 nm,
the cathode electrode is formed on the photoelectromotive layer on an n-type layer side,
the anode electrode is formed on the photoelectromotive layer on a p-type layer side, and
an optical path length of the light to a surface of the photoelectromotive layer in the first electrolytic solution is not more than 7 mm.
